(19) United States
(12) Patent Application Publication
(10) Pub. No.: US 2005/0287744 A1
(43) Pub. Date: Dec. 29, 2005

(54) Semiconductor device

(75) Inventors: Syotaro Ono, Kanagawa (JP); Yusuke Kawaguchi, Kanagawa (JP); Akio Nakagawa, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/157,908

(22) Filed: Jun. 22, 2005

(30) Foreign Application Priority Data
Jun. 23, 2004 (JP) 2004-184940

(51) Int. Cl. H01L 21/336; H01L 29/76; H01L 29/94; H01L 31/062; H01L 31/113; H01L 31/119

(52) U.S. Cl. 438/270; 257/288

(57) ABSTRACT

A semiconductor device has a plurality of pillars formed by filling a poly-silicon via an insulating layer in a plurality of trenches arranged substantially in parallel at certain intervals, n⁺-semiconductor regions and p⁺-semiconductor regions which are formed between partial pillars among the plurality of pillars and alternately formed along a direction where the pillars extend, n⁻-semiconductor regions arranged between the other partial neighboring pillars among the plurality of pillars and a first metal layer which makes a schottky contact on an upper face of the n⁻-semiconductor regions.

### CROSS REFERENCE TO RELATED APPLICATIONS

This application is based upon and claims the benefit of priority from the prior Japanese Patent Application No. 2004-184940, filed on Jun. 23, 2004, the entire contents of which are incorporated herein by reference.

### BACKGROUND OF THE INVENTION

1. Field of the Invention

The present invention relates to a semiconductor device in which trenches are formed, and intends, for example, a MOSFET having a vertical MOS (Metal Oxide Semiconductor) gate structure.

2. Related Art

In order to realize high-speed and high-efficiency performances of a power supply system, a power MOSFET used for synchronous rectification of a DC-DC converter is required to reduce an ON resistance and to improve properties of embedded diodes.

A MOSFET having trench gate structure are proposed as a techniques for reducing the ON resistance of the power MOSFET. In this type of MOSFET, it is possible to improve a channel density in the device by largely downsizing width of the trench and width of a cell. Especially, a MOSFET having trench gate structure of low voltage resistance can largely reduce the ON resistance of the device by reduction of a channel resistance. Therefore, the MOSFET having trench gate structure is widely used as a MOSFET for synchronous rectification in a DC-DC converter.

In the MOSFET for synchronous rectification in the DC-DC converter, the ON resistance of the device has to be reduced and the amount of electric charge at reverse recovery time has to be reduced in order to improve efficiency of a system. Therefore, a technique of embedding a schottky diode in the MOSFET has been proposed (see U.S. Pat. No. 6,351,018).

The MOSFET having trench gate structure, however, has an epitaxial layer with low resistance in the device, and there is a problem in which a leak current of the embedded schottky diode is large.

### SUMMARY OF THE INVENTION

According to one embodiment of the present invention, a semiconductor device, comprising:

a plurality of pillars formed by filling a poly-silicon via an insulating layer in a plurality of trenches arranged substantially in parallel at certain intervals;

n⁺-semiconductor regions and p⁺-semiconductor regions which are formed between partial pillars among the plurality of pillars and alternately formed along a direction where the pillars extend;

n⁻-semiconductor regions arranged between the other partial neighboring pillars among the plurality of pillars; and

a first metal layer which makes a schottky contact on an upper face of the n⁻-semiconductor regions.

Furthermore, according to one embodiment of the present invention, a semiconductor device, comprising:

a plurality of first pillars formed by filling a poly-silicon via an insulating layer in a plurality of first trenches arranged in a first direction at certain intervals;

n⁺-semiconductor regions and p⁺-semiconductor regions which are formed between partial pillars among the plurality of first pillars and alternately formed along a direction where the pillars extend;

a plurality of second pillars formed by filling a poly-silicon via an insulating layer in a plurality of second trenches arranged in a second direction different from the first direction at certain intervals;

n⁻-semiconductor regions arranged between the neighboring second pillars; and

a first metal layer which makes a schottky contact on an upper face of the n⁻-semiconductor regions.

### BRIEF DESCRIPTION OF THE DRAWINGS

FIG. 1 is a cross-sectional view in which main portions of a semiconductor device according to a first embodiment of the present invention are extracted.

FIG. 2 is a modified example of FIG. 1.

FIG. 3 is a cross-sectional view of a semiconductor device including the structure of FIG. 2.

FIG. 4 is a birds-eye view in a state of omitting the source metal layer 4 from FIG. 3.

FIG. 5 is a cross-sectional view of a semiconductor device according to the second embodiment of the present invention.

FIG. 6 is a birds-eye view in a state of omitting the source metal layer 4 from FIG. 5.

### DETAILED DESCRIPTION OF THE INVENTION

Hereafter, one embodiment of the present invention will be described more specifically with reference to the drawings.

### FIRST EMBODIMENT

FIG. 1 is a cross-sectional view in which main portions of a semiconductor device according to a first embodiment of the present invention are extracted. The semiconductor device in FIG. 1 has a plurality of pillars formed by filling conductive material (e.g. poly-silicon) via an insulating layer 2 in a plurality of trenches arranged to substantially parallel at certain intervals, a source metal layer 4 formed on the pillars 1, n-semiconductor regions 5 formed between the neighboring pillars 1, an n-drift layer 6 formed under the pillars 1, an n⁺-substrate 7 formed under the n-drift layer 6 and a drain metal layer 8 formed under the n⁺-substrate 7.

The pillars 1 function as a source. The conductive material 3 in the pillars 1 is desirably formed of a p-poly-silicon. The poly-silicon 3 is contacted the source metal layer 4.

The n⁻-semiconductor regions 5 and the source metal layer 4 have a schottky contact, and schottky diodes 9 are formed in dotted regions of FIG. 1.

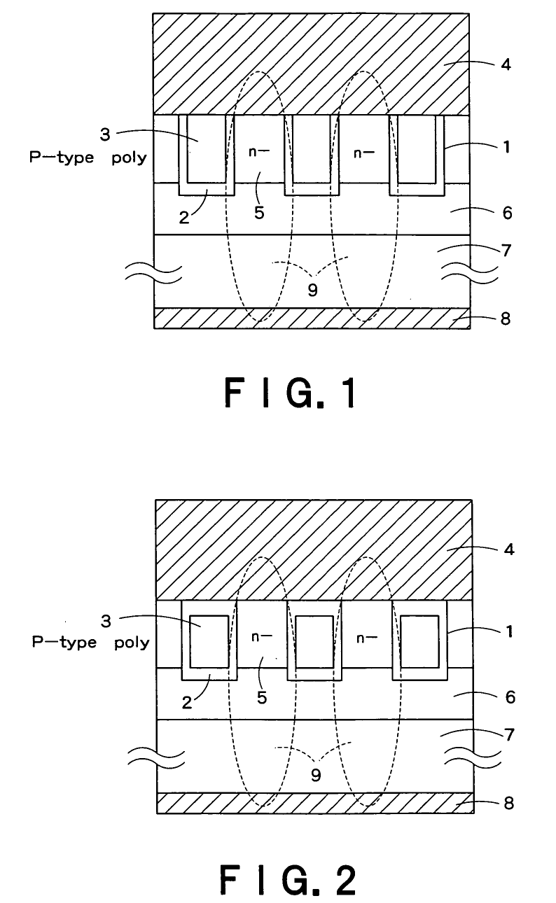

FIG. 2 is a modified example of FIG. 1. The poly-silicon in the pillars 1 is insulated by the source metal layer 4 and the insulating layer 2. Therefore, the poly-silicon 3 functions as the source or a gate. Although omitted in FIG. 2, the poly-silicon 3 contacts a source electrode or a gate electrode in somewhere of a device region.

The source metal layer 4 is arranged via the insulating layer 2 upwards the conductive material 3. Even in FIG. 2, the schottky diodes 9 are formed in the dotted regions.

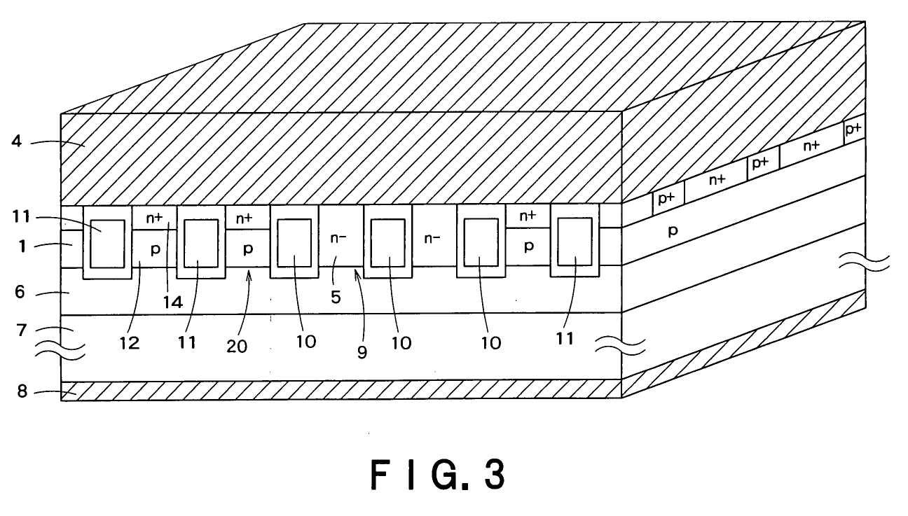

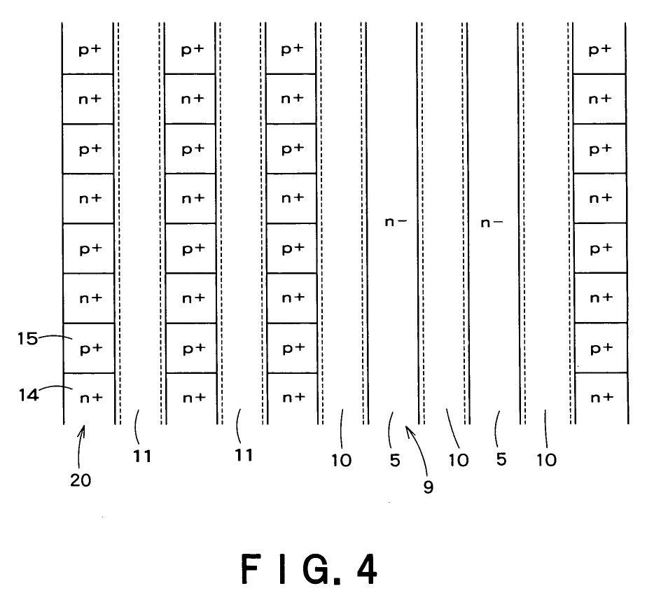

FIG. 3 is a cross-sectional view of a semiconductor device including the structure of FIG. 2. FIG. 4 is a birds-eye view in a state of omitting the source metal layer 4 from FIG. 3 for convenience of explanation. As shown in FIGS. 3 and 4, partial pillars among the pillars 1 arranged substantially in parallel at certain intervals are used for forming the MOSFETs 20, and the remaining pillars are used for forming the schttoky diodes.

P-well regions 12 formed by injecting boron ions in the n⁻-semiconductor regions on the n-drift layer 6 and n⁺-semiconductor regions 14 formed on the p-well region 12 are formed in regions for forming the MOSFETs. Channels are formed along a depth direction of the pillars 1. The electric current flows through the channels from the drains to the sources when the gate voltage is applied.

The n⁺-semiconductor regions 14 and the p⁺-semiconductor regions 15 are alternately formed as shown in FIG. 4. These regions make an ohmic contact with the source metal layer 4.

On the other hand, in a region where the schottky diodes 9 are formed, the n⁻-semiconductor regions 5 are formed between the neighboring pillars 1. The n⁻-semiconductor regions 5 are formed even in the direction where the pillars 1 extend.

With a layout shown in FIGS. 3 and 4, it is possible to reduce reverse direction leak current in the schottky diodes. The reason is because depletion layers extend in a direction from the pillars 1 to the n⁻-semiconductor regions 5 when the MOSFETs 5 are in OFF state. When the regions between the pillars 1 are n-type having impurity concentration lower than that of the n-drift layer 6, and distances between the neighboring pillars adjacent to the schottky diodes are wider than distances between the neighboring pillars adjacent to the MOSFETs 20, it is possible to effectively use schottky areas.

Accordingly, it is possible to reduce the leak current of the schottky diodes 9 by the depletion layers. If the poly-silicon 10 in the pillars 1 neighboring to the schottky diodes 9 are p types, the depletion layers further enlarge at time of applying the drain current. Therefore, the electric field is not applied between the pillars 1, thereby further reducing leak current. Due to such a reason, it is desirable to provide a p-type poly-silicon 10.

A ratio between the number of the MOSFETs 20 and the number of the schottky diodes 9 is not specially limited. The ratio is desirably set to a proper value according to applications. The distances between the neighboring pillars 1 in the regions where the schottky diodes 9 are formed is desirably set to be longer than the distances between the neighboring pillars 1 in the regions where the MOSFETs 20 are formed.

As described above, according to the first embodiment, the MOSFETs 20 are formed along partial pillars 1 among a plurality of pillars 1, and the schottky diodes 9 are formed along the other partial pillars 1. When the MOSFETs 20 are in OFF-state, the depletion layers extend from the pillars adjacent to the schottky diodes 9 to the n⁻-semiconductor regions 5. Therefore, even when the drain voltage is applied, it is possible to surely restrain the reverse direction leak current.

Since the conductive materials 10 and 11 are formed by using the same material (e.g. poly-silicon), it is possible to simplify fabrication process. The conductive material 11 is desirably formed of an n-type poly-silicon to connect with the gate, and the conductive material 10 is desirably formed of a p-type poly-silicon to connect with the source.

### SECOND EMBODIMENT

In a second embodiment, the schottky diodes 9 are formed in a direction different from a direction where the MOSFETs 20 are formed.

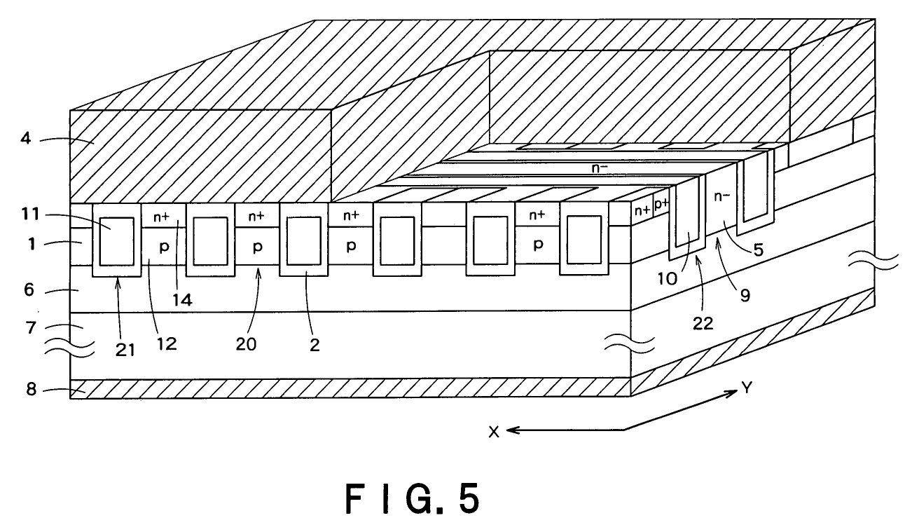

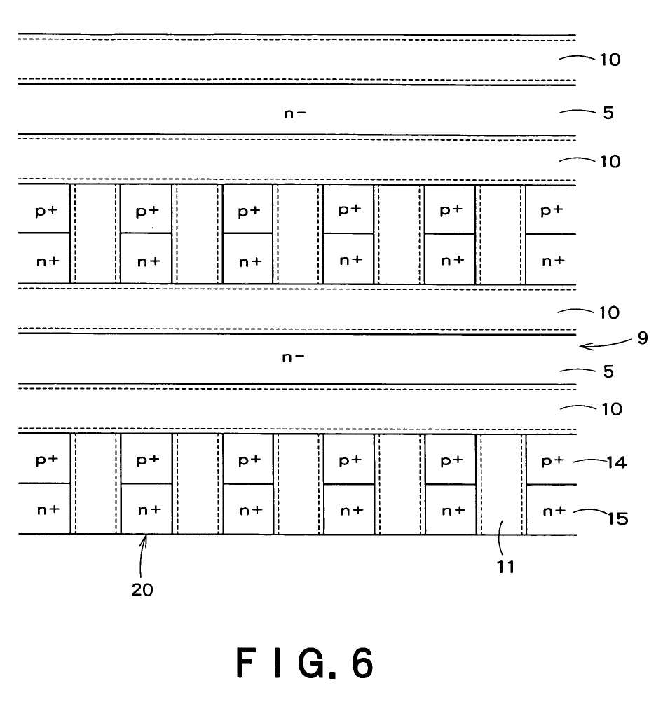

FIG. 5 is a cross-sectional view of a semiconductor device according to the second embodiment of the present invention. FIG. 6 is a birds-eye view in a state of omitting the source metal layer 4 from FIG. 5 for convenience of explanation. In FIG. 5, the same reference numerals are attached to constituents common to FIG. 3. Hereinafter, points difference from the first embodiment will be mainly described. In FIG. 5, the source metal layer 4 is partially omitted for convenience of explanation. Practically, the source metal layer 4 is covered on the upper face of FIG. 5.

The semiconductor device according to the second embodiment has a plurality of pillars 21 and 22 formed along the trenches extending in two directions orthogonal to each other. The first pillars 21 formed in X direction are used as the gates of the MOSFETs 20. The second pillars 22 formed in Y direction are formed for leak current reduction of the schottky diodes 9.

The gates made of the n type poly-silicon are formed via the insulating layer in the first pillars 21. The p-well regions 12 and the n⁺-semiconductor regions 14 formed thereon are formed between the neighboring first pillars 21. The n⁺-semiconductor regions 14 and the p⁺-semiconductor regions 15 are alternately formed in a direction where the first pillars 21 extends, as shown in FIG. 6.

On the other hand, the sources 10 made of the p-type poly-silicon are formed in the second pillars 22 in the region where the schottky diodes 9 are formed. The p-type poly-silicon layers are directly contacted the source metal layer 4. The n⁻-semiconductor layers 5 are formed between the neighboring second pillars 22. The n-semiconductor regions 5 and the source metal layer 4 make the schottky contact. The schottky diodes 9 are formed with the schottky contact. The n⁻-semiconductor regions 5 extend even in the direction where the second pillars 22 extend, as shown in FIG. 6.

The distances between the second pillars 22 located at both sides of the regions where the schottky diodes are formed are set to be longer than the distances between the first pillars 21 located at both ends of the regions where the MOSFETs 20 are formed.

Even in the second embodiment, when the MOSFETs 20 turn off, the depletion layers extend in a direction from the second pillars 22 to the n-semiconductor region 5 in a region where the schottky diodes 9 are formed. Therefore, it is possible to reduce the leak current of the schottky diodes 9. In the second embodiment, the MOSFETs 20 and the schottky diodes 9 can be formed in directions different from each other, thereby increasing freedom of layout.

In the second embodiment, similarly to the first embodiment, even if the conductive material 11 in the first pillars 21 may be set to the same voltage as that of the conductive material 10 in the second pillars 22, advantageous effect of the present invention is obtained. The conductive material 10 is desirably p-type and connected to the source.

1. A semiconductor device, comprising:
a plurality of pillars formed by filling a poly-silicon via an insulating layer in a plurality of trenches arranged substantially in parallel at certain intervals;
n⁺-semiconductor regions and p⁺-semiconductor regions which are formed between partial pillars among the plurality of pillars and alternately formed along a direction where the pillars extend;
n⁻-semiconductor regions arranged between the other partial neighboring pillars among the plurality of pillars; and
a first metal layer which makes a schottky contact on an upper face of the n⁻-semiconductor regions.

2. A semiconductor device according to claim 1, wherein the poly-silicon in at least one of the pillars arranged at both sides of the n⁻-semiconductor regions is p-type, and the poly-silicon in at least one of the pillars arranged at both sides of the n⁺-semiconductor regions and the p⁺-semiconductor regions is n-type.

3. A semiconductor device according to claim 1, wherein distances between the pillars at both sides of the n⁻-semiconductor regions are longer than distances between the pillars at both sides of the n⁺-semiconductor regions and the p⁺-semiconductor regions.

4. A semiconductor device according to claim 1, wherein the first metal layer makes an ohmic contact with the n⁺-semiconductor regions and the p⁺-semiconductor regions.

5. A semiconductor device according to claim 1, wherein each of the plurality of pillars is a source or a gate.

6. A semiconductor device according to claim 5, wherein the pillars adjacent to the n⁺-semiconductor regions and the p⁺-semiconductor regions are gates of MOSFETs.

7. A semiconductor device according to claim 1, wherein the first metal layer is arranged via an insulating layer on the plurality of pillars.

8. A semiconductor device according to claim 1, wherein the plurality of pillars are directly connected to the first metal layer arranged thereon.

9. A semiconductor device according to claim 1, further comprising:
an n-drift layer arranged under the plurality of pillars;
an n⁺-substrate arranged under the n-drift layer; and
a second metal layer arranged under the n⁺-substrate,
wherein the first metal layer is a source; and
the second metal layer is a drain.

10. A semiconductor device according to claim 9, wherein impurity concentration of the n⁻-semiconductor regions is lower than that of the n-drift layer.

11. A semiconductor device, comprising:
a plurality of first pillars formed by filling a poly-silicon via an insulating layer in a plurality of first trenches arranged in a first direction at certain intervals;
n⁺-semiconductor regions and p⁺-semiconductor regions which are formed between partial pillars among the plurality of first pillars and alternately formed along a direction where the pillars extend;
a plurality of second pillars formed by filling a poly-silicon via an insulating layer in a plurality of second trenches arranged in a second direction different from the first direction at certain intervals;
n⁻-semiconductor regions arranged between the neighboring second pillars; and
a first metal layer which makes a schottky contact on an upper face of the n⁻-semiconductor regions.

12. A semiconductor device according to claim 11, wherein the poly-silicon in at least one of the second pillars at both sides of the n⁻-semiconductor regions is p-type; and
the poly-silicon in at least one of the first pillars at both sides of the n⁺-semiconductor regions and the p⁺-semiconductor regions is n-type.

13. A semiconductor device according to claim 11, wherein each of the second pillars is a gate or a source.

14. A semiconductor device according to claim 11, wherein distances between the second pillars at both sides of the n⁻-semiconductor regions are longer than distances between the first pillars at both sides of the n⁺-semiconductor regions and the p⁺-semiconductor regions.

15. A semiconductor device according to claim 11, wherein the first metal layer makes an ohmic contact with the n⁺-semiconductor regions and the p⁺-semiconductor regions.

16. A semiconductor device according to claim 11, wherein the first pillars adjacent to the n⁺-semiconductor regions and the p⁺-semiconductor regions are gates of the MOSFETs.

17. A semiconductor device according to claim 11, wherein the first metal layer is arranged via the insulating layer on the first and second pillars.

18. A semiconductor device according to claim 11, wherein the first and second pillars are directly connected to the first metal layer thereon.

19. A semiconductor device according to claim 11, further comprising:
an n-drift layer arranged under the plurality of first pillars and second pillars;
an n⁺-substrate arranged under the n-drift layer; and
a second metal layer arranged under the n⁺-substrate,
wherein the first metal layer is a source; and
the second metal layer is a drain.

20. A semiconductor device according to claim 11, wherein impurity concentration of the n⁻-semiconductor regions is lower than that of the n-drift layer.
